(19) United States
(12) Patent Application Publication
(10) Pub. No.: US 2025/0386636 A1
(43) Pub. Date: Dec. 18, 2025

(54) DISPLAY DEVICE

(71) Applicant: LG DISPLAY CO., LTD., Seoul (KR)

(72) Inventors: Jaebin SONG, Seoul (KR); Seung-Ju MUN, Paju-si (KR)

(73) Assignee: LG DISPLAY CO., LTD., Seoul (KR)

(21) Appl. No.: 19/093,128

(22) Filed: Mar. 27, 2025

(30) Foreign Application Priority Data
Jun. 17, 2024 (KR) 10-2024-0078525

(51) Int. Cl. H10H 29/39; H10H 29/01; H10H 29/80; H10H 29/855

(52) U.S. Cl. CPC H10H 29/39; H10H 29/012; H10H 29/8552; H10H 29/882

(57) ABSTRACT

A display device includes a substrate; at least one pixel driving circuit disposed on the substrate; a plurality of bank patterns disposed on the pixel driving circuit; a plurality of light-emitting elements disposed on each of the plurality of bank patterns and electrically connected to the pixel driving circuit; at least one optical layer disposed to surround the plurality of light-emitting elements; and a black matrix disposed on the optical layer and overlapping at least one of the light-emitting elements, wherein the at least one optical layer includes a first optical layer, a second optical layer, and a third optical layer.

### CROSS-REFERENCE TO RELATED APPLICATION

This application claims priority from Korean Patent Application No. 10-2024-0078525 filed on Jun. 17, 2024, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device including a light-emitting element.

### Discussion of the Related Art

Display devices are applied to various electronic devices such as TV, mobile phones, laptops, and tablets. To this end, research is being conducted to develop a thinner, lighter, and low power consumption display device.

Among the display devices, a light-emitting display device includes a self-light-emitting element, and displays an image using light generated from the self-light-emitting element. The display device including the self-light-emitting element may be implemented to be thin, and may be flexible to implement various types of display devices such as foldable, bendable, or rollable display devices.

The display device including the self-light-emitting element may include, for example, a light-emitting display device (LED display device) including the light-emitting element made of an inorganic material

The inorganic light-emitting display device is attracting attention as a next-generation display device because the device includes the light-emitting element made of the inorganic material resistant to moisture and oxygen, and thus is less affected by the external environment and thus has high reliability and high image quality.

### SUMMARY

Accordingly, embodiments of the present disclosure are directed to a display device that substantially obviates one or more of the problems due to limitations and disadvantages of the related art.

An aspect of the present disclosure is to provide a display device with improved light extraction efficiency.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise a substrate; at least one pixel driving circuit disposed on the substrate; a plurality of bank patterns disposed on the pixel driving circuit; a plurality of light-emitting elements disposed on each of the plurality of bank patterns and electrically connected to the pixel driving circuit; at least one optical layer disposed to surround the plurality of light-emitting elements; and a black matrix disposed on the optical layer and overlapping at least one of the light-emitting elements, wherein the at least one optical layer includes a first optical layer, a second optical layer, and a third optical layer.

In another aspect, a display device may comprise a substrate; at least one pixel driving circuit disposed on the substrate; a plurality of bank patterns disposed on the pixel driving circuit; a plurality of light-emitting elements disposed on each of the plurality of bank patterns and electrically connected to the pixel driving circuit; a first optical layer surrounding each of the plurality of light-emitting elements; and a second optical layer disposed on an outer side of the first optical layer, wherein a horizontal width of the first optical layer increases as the first optical layer extends from a lower surface to an upper surface thereof.

In another aspect, a method for manufacturing a display device may comprise: forming a bank pattern on a substrate; disposing a plurality of light-emitting elements on the bank pattern; forming a second optical layer on the substrate such that the second optical layer has one or more open areas defined therein exposing the bank pattern and the plurality of light-emitting elements; forming a first optical layer filling the open area so as to surround the bank pattern and surround a side surface of each of the plurality of light-emitting elements; and disposing a second electrode on the plurality of light-emitting elements, the first optical layer, and the second optical layer. Details of other embodiments are included in the detailed description and drawings.

According to an embodiment of the present disclosure, the display device having improved light extraction efficiency by increasing an amount of light incident from the light-emitting element to the first optical layer may be realized.

As a result, the display device capable of operating at a low power level to reduce power consumption may be realized.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles.

FIG. 1 is a schematic plan view of a display device according to an embodiment of the present disclosure.

FIG. 2 is an enlarged view of a display device according to an embodiment of the present disclosure.

FIGS. 3 to 6 are enlarged plan views of a display area of a display device according to an embodiment of the present disclosure.

FIG. 7 is a cross-sectional view of a display device according to an embodiment of the present disclosure.

FIG. 8 is a schematic enlarged plan view of a first sub-pixel of a display device according to an embodiment of the present disclosure.

FIGS. 9 to 14 are diagrams illustrating a method for manufacturing a display device according to an embodiment of the present disclosure.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. An area size and a thickness of each component shown in the drawing are shown for convenience of illustration, and the present disclosure is not necessarily limited to the area size and the thickness of the component as shown.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc. should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

Hereinafter, various embodiments of the present disclosure will be described in detail with reference to the accompanying drawings.

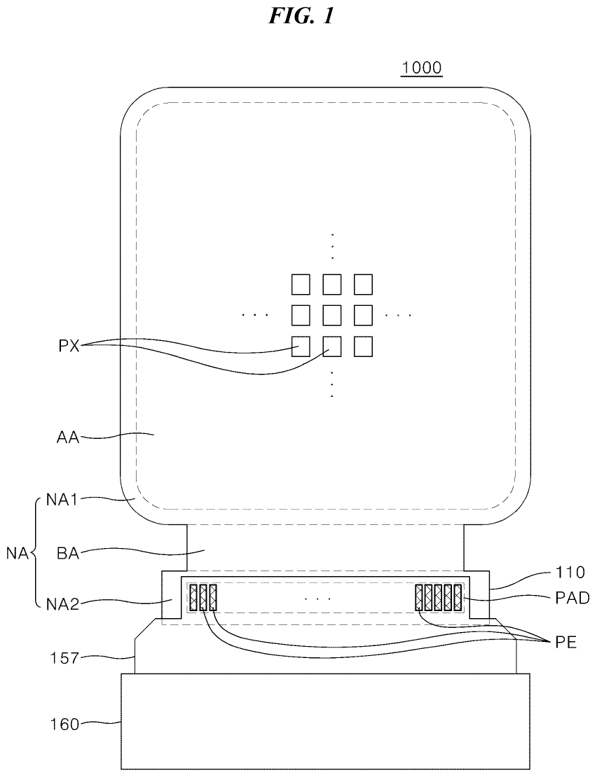

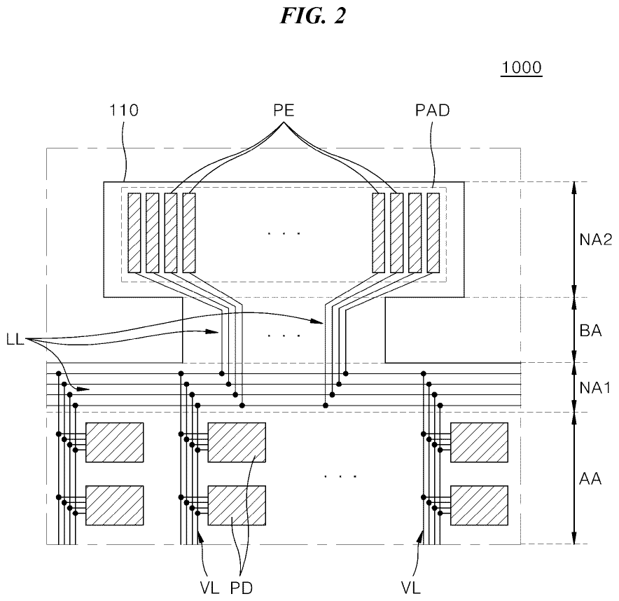

FIG. 1 is a schematic plan view of a display device according to an embodiment of the present disclosure. FIG. 2 is an enlarged view of a display device according to an embodiment of the present disclosure.

Referring to FIGS. 1 and 2, a display device 1000 according to an embodiment of the present disclosure includes a substrate 110. The substrate 110 is a member that supports other components of the display device 1000. The substrate 110 may be made of an insulating material. For example, the substrate 110 may be made of glass or resin. In addition, the substrate 110 may be made of a material having flexibility. For example, the substrate 110 may be made of a plastic material having flexibility, such as polyimide (PI).

The substrate 110 includes a display area AA and a non-display area NA. The display area AA is an area in which an image is displayed, and the non-display area NA is an area in which an image is not displayed. The non-display area NA includes a first non-display area NA1, a bending area BA, and a second non-display area NA2. In this case, the distinction between the display area AA and the non-display area NA is applied not only to the substrate 110 but also to the display device 1000 and each of the other components of the display device 1000.

First, the display area AA is an area for displaying an image. In order to display an image, a plurality of pixels PX and a pixel driving circuit PD for driving the plurality of pixels PX may be disposed in the display area AA. The plurality of pixels PX constitute the display area AA, and one pixel PX may be composed of a plurality of sub-pixels. The light-emitting element may be disposed in each of the plurality of sub-pixels. A type of each of the plurality of light-emitting elements may vary according to a type of the display device 1000. For example, when the display device 1000 is an inorganic light-emitting display device, the light-emitting element may be a light-emitting diode (LED), or a micro light-emitting diode (LED). However, embodiments of the present disclosure are not limited thereto.

The non-display area NA is an area in which no image is displayed. Various lines and circuits for driving the pixels PX of the display area AA are disposed in the non-display area NA. For example, a driving circuit such as a data driver and a gate driver, a pad PAD connected to driving components such as a flexible film 157 and a printed circuit board 160, and a link line LL for transmitting a signal may be disposed in the non-display area NA.

The non-display area NA may include a first non-display area NA1, a bending area BA, and a second non-display area NA2. For example, the first non-display area NA1 may be an area surrounding at least a portion of the display area AA. The bending area BA is an area extending from at least one of a plurality of sides of the first non-display area NA1 and may be a bendable area. The second non-display area NA2 may be an area extending from the bending area BA, and the pad PAD may be disposed in the second non-display area. For example, the bending area BA may be in a bent state, and the remaining area of the substrate 110 except for the bending area BA may be in a flat state. In this case, as the bending area BA is bent, the second non-display area NA2 may be located on a rear surface of the display area AA. However, embodiments of the present disclosure are not limited thereto.

The display area AA of the substrate 110 may be formed in various shapes according to the designs of the display device 1000. For example, the display area AA may be formed in a rectangular shape having four corners of a round shape. However, embodiments of the present disclosure are not limited thereto. In another example, the display area AA may be formed in a rectangular shape in which four corners have a right angle or a circular shape. However, embodiments of the present disclosure are not limited thereto.

A width of the second non-display area NA2 in which a plurality of pad electrodes PE are disposed may be greater than a width of the bending area BA in which only a plurality of link lines LL are disposed. In addition, the width of the display area AA in which the plurality of sub-pixels are disposed may be greater than the width of the bending area BA in which only the plurality of link lines LL are disposed. Although the width of the bending area BA is illustrated as being smaller than the width of the remaining area of the substrate 110 in the drawing, a shape of the substrate 110 including the bending area BA is merely an example, and embodiments of the present disclosure are not limited thereto.

The pad PAD including the plurality of pad electrodes PE is disposed in the second non-display area NA2. The driving component including one or more flexible films 157 and the printed circuit board 160 may be bonded to the pad PAD. The plurality of pad electrodes PE of the pad PAD may be electrically connected to the one or more flexible films 157 to transmit various signals from the printed circuit board 160 and the flexible film 157 to a plurality of pixel driving circuits PD of the display area AA.

The flexible film 157 has a structure in which various components are disposed on a flexible base film. For example, a driving IC such as a gate driver IC and a data driver IC may be disposed on the flexible film 157. The driving IC is a component that processes data and a driving signal for displaying an image. The driving IC may be mounted in a manner such as a Chip On Glass (COG), a Chip On Film (COF), a Tape Carrier Package (TCP), or the like, depending on a mounted manner. The flexible film may be bonded onto the plurality of pad electrodes PE via a conductive adhesive layer.

The printed circuit board 160 is a component that is electrically connected to the plurality of flexible films 157 and supplies a signal to the driving IC. The printed circuit board 160 may be disposed at one end of the flexible film 157 so as to be electrically connected to the flexible film 157. Various components for supplying various signals to the driving IC may be disposed on the printed circuit board 160. For example, various components such as a timing controller, a power supply, a memory, a processor, etc. may be disposed on the printed circuit board 160.

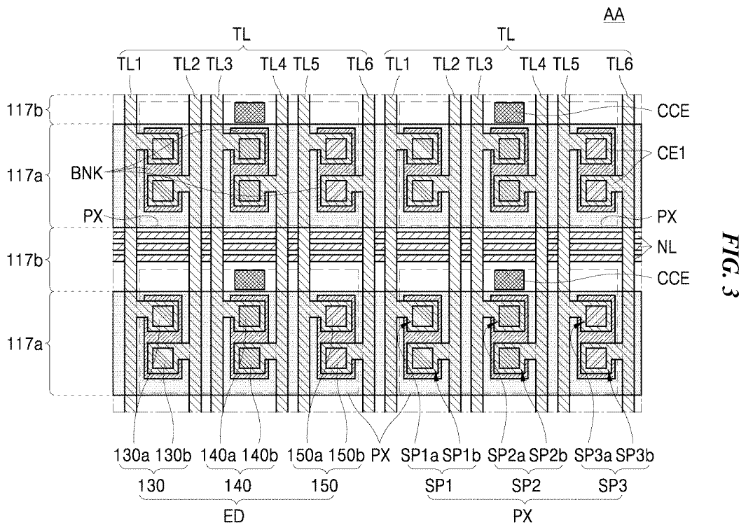

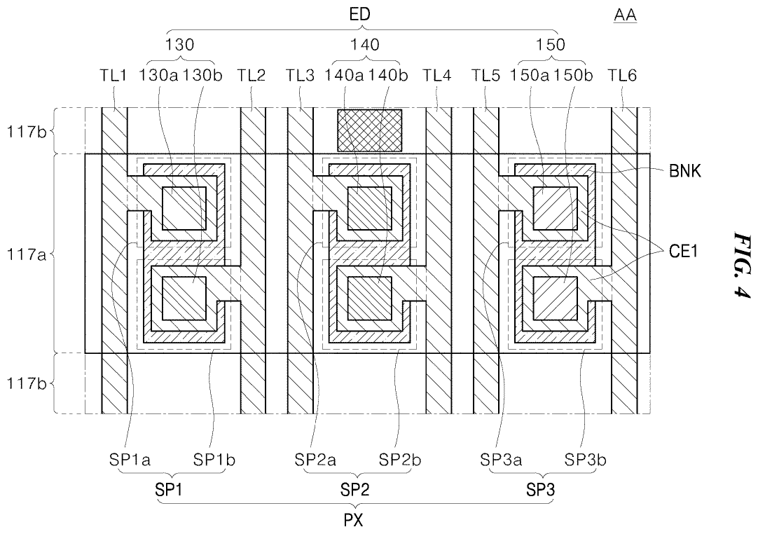

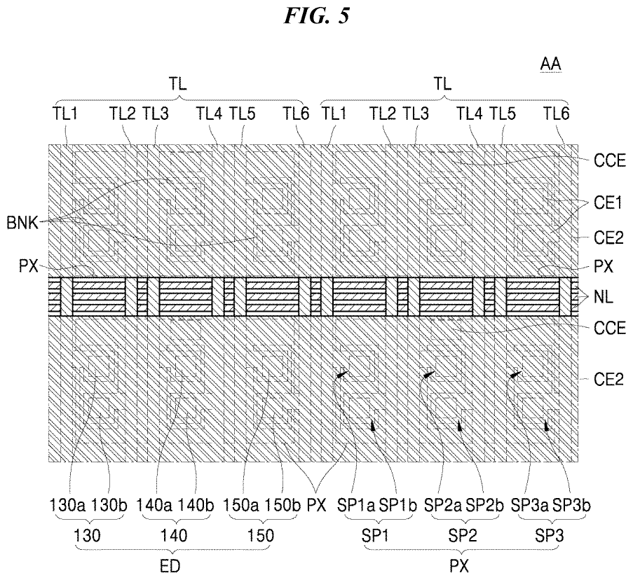

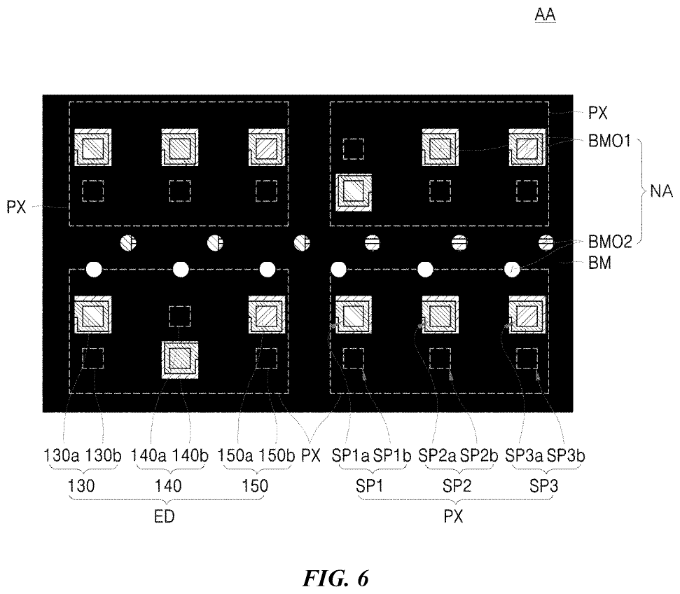

Hereinafter, FIGS. 3 to 6 are enlarged plan views of a display area of a display device according to an embodiment of the present disclosure. Specifically, FIG. 3 is an enlarged plan view of the display area AA including the plurality of pixels PX, and FIG. 4 is an enlarged plan view of the display area AA including one pixel PX. FIGS. 5 and 6 are enlarged plan views of the display area AA including the plurality of pixels PX. FIGS. 3 and 4 illustrate only a plurality of signal lines TL, a plurality of communication lines NL, a plurality of first electrodes CE1, a plurality of bank patterns BNK, and a plurality of light-emitting elements ED. FIG. 5 is an enlarged plan view in which a plurality of second electrodes CE2 are additionally disposed in FIG. 3, and FIG. 6 is an enlarged plan view in which a black matrix BM is additionally disposed in FIG. 5.

Referring to FIGS. 3 and 4, the plurality of pixels PX, each including a plurality of sub-pixels, are disposed in the display area AA. Each of the plurality of sub-pixels may include a light-emitting element ED to independently emit light. The plurality of sub-pixels may be arranged in a plurality of rows and a plurality of columns and thus may be arranged in a matrix form. However, embodiments of the present disclosure are not limited thereto. The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another thereof may be a green sub-pixel, and the other thereof may be a blue sub-pixel. A type of each of the plurality of sub-pixels is merely an example, and embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may include a 1-1 sub-pixel SP1a and a 1-2 sub-pixel SP1b. The pair of second sub-pixels SP2 may include a 2-1 sub-pixel SP2a and a 2-2 sub-pixel SP2b. The pair of third sub-pixels SP3 may include a 3-1 sub-pixel SP3a and a 3-2 sub-pixel SP3b. For example, one pixel PX may include a 1-1 sub-pixel SP1a and a 1-2 sub-pixel SP1b, a 2-1 sub-pixel SP2a and a 2-2 sub-pixel SP2b, and a 3-1 sub-pixel SP3a and a 3-2 sub-pixel SP3b. However, embodiments of the present disclosure are not limited thereto.

The plurality of sub-pixels constituting one pixel PX may be arranged in various manner. In one example, in one pixel PX, a pair of first sub-pixels SP1 may be arranged in the same column, a pair of second sub-pixels SP2 may be arranged in the same column, and a pair of third sub-pixels SP3 may be arranged in the same column. The first sub-pixel SP1, the second sub-pixel SP2, and the third sub-pixel SP3 may be arranged in the same row. The number and arrangement of the plurality of sub-pixels constituting one pixel PX are examples, and embodiments of the present disclosure are not limited thereto.

The plurality of signal lines TL may be disposed in an area between adjacent ones of the plurality of sub-pixels. The plurality of signal lines TL may extend in the column direction while being disposed between adjacent ones of the plurality of sub-pixels. The plurality of signal lines TL may be lines for transmitting an anode voltage from the pixel driving circuit PD to the plurality of sub-pixels. For example, the plurality of signal lines TL may be electrically connected to the plurality of pixel driving circuits PD and the first electrodes CE1 of the plurality of sub-pixels. The anode voltage output from the pixel driving circuit PD may be transmitted to the first electrodes CE1 of the plurality of sub-pixels via the plurality of signal lines TL. In this regard, the first electrode CE1 may be an electrode electrically connected to the anode electrode 134 of the light-emitting element ED. Accordingly, the anode voltage from the signal line TL may be transmitted to the anode electrode 134 of the light-emitting element ED via the first electrode CE1.

Therefore, a structure of the display device 1000 may be simplified using the pixel driving circuit PD in which the plurality of pixel circuits are integrated with each other, instead of forming a plurality of transistors and a storage capacitor in each of the plurality of sub-pixels. In addition, as circuits respectively disposed in the plurality of sub-pixels are integrated into one pixel driving circuit PD, high-efficiency low-power operation of the display device may be achieved.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first sub-pixels SP1, respectively. The third signal line TL3 and the fourth signal line TL4 may be electrically connected to the pair of second sub-pixels SP2, respectively. The fifth signal line TL5 and the sixth signal line TL6 may be electrically connected to the pair of third sub-pixels SP3, respectively.

The first signal line TL1 may be disposed on one side of the pair of first sub-pixels SP1, and the first signal line TL1 may be disposed on the other side of the pair of first sub-pixels SP1. The first signal line TL1 may be electrically connected to one first sub-pixel SP1 of the pair of first sub-pixels SP1, for example, the first electrode CE1 of the 1-1 sub-pixel SP1a. The second signal line TL2 may be electrically connected to the other first sub-pixel SP1 of the pair of first sub-pixels SP1, for example, the first electrode CE1 of the 1-2 sub-pixel SP1b.

The third signal line TL3 may be disposed on one side of the pair of second sub-pixels SP2, and the fourth signal line TL4 may be disposed on the other side of the pair of second sub-pixels SP2. For example, the third signal line TL3 may be disposed adjacent to the second signal line TL2. The third signal line TL3 may be electrically connected to one second sub-pixel SP2 of the pair of second sub-pixels SP2, for example, the first electrode CE1 of the 2-1 sub-pixel SP2a. The fourth signal line TL4 may be electrically connected to the other second sub-pixel SP2 of the pair of second sub-pixels SP2, for example, the first electrode CE1 of the 2-1 sub-pixel SP2b.

The fifth signal line TL5 may be disposed on one side of the pair of third sub-pixels SP3, and a sixth signal line TL6 may be disposed on the other side of the pair of third sub-pixels SP3. For example, the fifth signal line TL5 may be disposed adjacent to the fourth signal line TL4. The sixth signal line TL6 may be disposed adjacent to the first signal line TL1 connected to the pixel PX adjacent thereto. The fifth signal line TL5 may be electrically connected to one third sub-pixel SP3 of the pair of third sub-pixels SP3, for example, the first electrode CE1 of the 3-1 sub-pixel SP3a. The sixth signal line TL6 may be electrically connected to the other third sub-pixel SP3 of the pair of third sub-pixels SP3, for example, the first electrode CE1 of the 3-2 sub-pixel SP3b.

Each of the plurality of signal lines TL may be made of a conductive material. For example, each of the plurality of signal lines TL may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. However, embodiments of the present disclosure are not limited thereto. In another example, each of the plurality of signal lines TL may have a multilayer structure made of a conductive material. For example, each of the plurality of signal lines TL may have a multilayer structure of a titanium (Ti) layer/aluminum (Al) layer/titanium (Ti) layer/indium tin oxide (ITO) layer. However, embodiments of the present disclosure are not limited thereto.

A plurality of communication lines NL may be disposed in an area between adjacent ones of the plurality of pixels PX. The plurality of communication lines NL may extend in the row direction while being disposed in an area between adjacent ones of the plurality of pixels PX. The plurality of communication lines NL may be disposed in an area between adjacent ones of the plurality of second electrodes CE2 and may not overlap the plurality of second electrodes CE2. For example, the plurality of communication lines NL may be lines used for short-range communication such as near field communication (NFC). The plurality of communication lines NL may function as antennas.

According to the present disclosure, a bank pattern BNK may be disposed in each of the plurality of sub-pixels. Each of the plurality of bank patterns BNK may be a structure in which each of the plurality of light-emitting elements ED is seated. The plurality of bank patterns BNK may guide positions of the plurality of light-emitting elements ED in a transfer process of transferring the plurality of light-emitting elements ED to the substrate, respectively. In the transfer process of the plurality of light-emitting elements ED thereto, the plurality of light-emitting elements ED may be transferred onto the plurality of bank patterns BNK, respectively.

The bank pattern BNK of the first sub-pixel SP1, the bank pattern BNK of the second sub-pixel SP2, and the bank pattern BNK of the third sub-pixel SP3 may be spaced apart from each other. The bank pattern BNK of the first sub-pixel SP1, the bank pattern BNK of the second sub-pixel SP2, and the bank pattern BNK of the third sub-pixel SP3 may be constructed to be isolated from each other. Accordingly, the bank patterns BNK of the first sub-pixel SP1, the second sub-pixel SP2, and the third sub-pixel SP3 to which different types of light-emitting elements ED are transferred, respectively may be easily identified.

The bank pattern BNK of the 1-1 sub-pixel SP1a and the bank pattern BNK of the 1-2 sub-pixel SP1b may be connected to each other, or may be spaced apart or isolated from each other. For example, the bank pattern BNK of the (1-1)-th sub-pixel SP1a and the bank pattern BNK of the 1-2 sub-pixel SP1b in which the light-emitting elements ED of the same type are disposed, respectively may be connected to each other, or may be spaced apart or isolated from each other in consideration of a design such as a transfer process requirement. In addition, the bank pattern BNK of the 2-1 sub-pixel SP2a and the bank pattern BNK of the 2-2 sub-pixel SP2b may be connected to each other, or may be spaced apart or isolated from each other. The bank pattern BNK of the 3-1 sub-pixel SP3a and the bank pattern BNK of the 3-2 sub-pixel SP3b may be connected to each other, or may be spaced apart or isolated from each other. Accordingly, the bank patterns BNK of the pair of first sub-pixels SP1, the bank patterns BNK of the pair of second sub-pixels SP2, and the bank patterns BNK of the pair of third sub-pixels SP3 may be variously formed. Embodiments of the present disclosure are not limited thereto.

Each of the plurality of bank patterns BNK may be made of an organic insulating material. Each of the plurality of bank patterns BNK may be formed as a single layer or multiple layers made of an organic insulating material. For example, each of the plurality of bank patterns BNK may be made of photoresist, polyimide (PI), or an acryl-based material. However, embodiments of the present disclosure are not limited thereto.

The first electrode CE1 may be disposed in each of the plurality of sub-pixels SP. The first electrode CE1 may be disposed on the bank pattern BNK. The first electrode CE1 may be electrically connected to one signal line TL among the plurality of signal lines TL. At least a portion of the first electrode CE1 may extend outwardly of the bank pattern BNK and may be electrically connected to the signal line TL closest to the first electrode CE1. For example, a portion of the first electrode CE1 of the 1-1 sub-pixel SP1a may extend to one side area of the 1-1 sub-pixel SP1a so as to be electrically connected to the first signal line TL1, and a portion of the first electrode CE1 of the 1-2 sub-pixel SP1b may extend to the other side area of the 1-2 sub-pixel SP1b so as to be electrically connected to the second signal line TL2. A portion of the first electrode CE1 of the 2-1 sub-pixel SP2a may extend to one side area of the 2-1 sub-pixel SP2a so as to be electrically connected to the third signal line TL3, and a portion of the first electrode CE1 of the 2-1 sub-pixel SP2b may extend to the other side area of the 2-1 sub-pixel SP2b so as to be electrically connected to the fourth signal line TL4. A portion of the first electrode CE1 of the 3-1 sub-pixel SP3a may extend to one side area of the 3-1 sub-pixel SP3a so as to be electrically connected to the fifth signal line TL5, and a portion of the first electrode CE1 of the 3-2 sub-pixel SP3b may extend to the other side area of the 3-2 sub-pixel SP3b so as to be electrically connected to the sixth signal line TL6.

The first electrode CE1 may be electrically connected to the anode electrode 134 of the light-emitting element ED, and may transmit an anode voltage from the pixel driving circuit PD to the light-emitting element ED via the signal line TL. Different voltages may be respectively applied to the first electrodes CE1 of the plurality of sub-pixels based on a displayed image. That is, different voltages may be applied to the first electrodes CE1 of the plurality of sub-pixels SP, respectively. Accordingly, the first electrode CE1 may be a pixel electrode, and embodiments of the present disclosure are not limited thereto.

The first electrode CE1 may be made of a conductive material. More specifically, the first electrode CE1 may be integrally formed with the plurality of signal lines TL. For example, the first electrode CE1 may be made of the same conductive material as that of each of the plurality of signal lines TL. However, embodiments of the present disclosure are not limited thereto. For example, the first electrode CE1 may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. However, embodiments of the present disclosure are not limited thereto. In another example, the first electrode CE1 may be configured to have a multilayer structure made of a conductive material. For example, each of the plurality of first electrodes CE1 may have a multilayer structure of a titanium (Ti) layer/aluminum (Al) layer/titanium (Ti) layer/indium tin oxide (ITO) layer. However, embodiments of the present disclosure are not limited thereto.

The light-emitting element ED may be disposed in each of the plurality of sub-pixels. The plurality of light-emitting elements ED may be one of a light-emitting diode (LED) or a micro light-emitting diode (LED). However, embodiments of the present disclosure are not limited thereto. The plurality of light-emitting elements ED may be disposed on the bank pattern BNK and the first electrode CE1. The plurality of light-emitting elements ED may be disposed on the first electrode CE1 and may be electrically connected to the first electrode CE1. Accordingly, the light-emitting element ED may receive the anode voltage from the pixel driving circuit PD via the signal line TL and the first electrode CE1 to emit light.

The plurality of light-emitting elements ED may include a first light-emitting element 130, a second light-emitting element 140, and a third light-emitting element 150. The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another thereof may be a green light-emitting element, and the other thereof may be a blue light-emitting element. However, embodiments of the present disclosure are not limited thereto. Accordingly, various colors of light including white may be implemented by combining red light, green light, and blue light respectively emitted from the plurality of light-emitting elements ED from each other. However, the type of each of the plurality of light-emitting elements ED is merely an example, and embodiments of the present disclosure are not limited thereto.

The first light-emitting element 130 may include a 1-1 light-emitting element 130a disposed in the 1-1 sub-pixel SP1a and a 1-2 light-emitting element 130b disposed in the 1-2 sub-pixel SP1b. The second light-emitting element 140 may include a 2-1 light-emitting element 140a disposed in the 2-1 sub-pixel SP2a and a 2-2 light-emitting element 140b disposed in the 2-2 sub-pixel SP2b. The third light-emitting element 150 may include a 3-1 light-emitting element 150a disposed in the 3-1 sub-pixel SP3a and a 3-2 light-emitting element 150b disposed in the 3-2 sub-pixel SP3b.

Referring to FIGS. 3 and 4 together, a first optical layer 117a is disposed in each of the plurality of sub-pixels SP. The first optical layer 117a may be disposed to surround each of the plurality of light-emitting elements ED. For example, the first optical layer 117a may be disposed commonly in at least some pixels PX among the plurality of pixels PX arranged in the same row. For example, one first optical layer 117a may be disposed in the plurality of pixels PX. One first optical layer 117a may be commonly disposed in a combination of the n sub-pixels SP.

In this regard, the first optical layer 117a may be disposed in each of the plurality of pixels PX, or may be commonly disposed in a combination of some pixels PX arranged in the same row. That is, the first optical layer 117a may be disposed in each of the plurality of pixels PX, or the plurality of pixels PX may share one first optical layer 117a with each other. In addition, each of the plurality of sub-pixels SP may separately include the first optical layer 117a. However, embodiments of the present disclosure are not limited thereto.

The first optical layer 117a may be made of an organic insulating material in which light scattering particles are dispersed. For example, the first optical layer 117a may be made of siloxane in which fine metal particles such as titanium dioxide (TiO₂) particles are dispersed. However, embodiments of the present disclosure are not limited thereto. Light from the plurality of light-emitting elements ED may be scattered by the light scattering particles dispersed in the first optical layer 117a so as to be emitted to the outside. The first optical layer 117a may improve extraction efficiency of the light emitted from the plurality of light-emitting elements ED.

A second optical layer 117b may be disposed on an outer side of the first optical layer 117a. A third optical layer 117c may be disposed on the first optical layer 117a. For example, the second optical layer 117b may be disposed to surround the first optical layer 117a. The second optical layer 117b may be in contact with a side surface of the first optical layer 117a. The second optical layer 117b may be disposed in an area between adjacent ones of the plurality of pixels PX. The second optical layer 117b may be disposed on the contact electrode CCE and the plurality of communication lines NL.

The second optical layer 117b may be made of an organic insulating material. The second optical layer 117b may be made of the same organic insulating material as that of the first optical layer 117a. The first optical layer 117a may include light scattering particles, while the second optical layer 117b may not include light scattering particles. For example, the second optical layer 117b may be made of siloxane. However, embodiments of the present disclosure are not limited thereto.

Referring to FIGS. 3, 4, and 5 together, the second electrode CE2 is disposed in each of the plurality of sub-pixels SP. The second electrode CE2 may be disposed on the light-emitting element ED. The second electrode CE2 may be electrically connected to the pixel driving circuit PD via a plurality of contact electrodes CCE. Further, the second electrode CE2 may be electrically connected to the cathode electrode 135 of the light-emitting element ED to transmit the cathode voltage from the pixel driving circuit PD to the light-emitting element ED. The same cathode voltage may be applied to the second electrodes CE2 of the plurality of sub-pixels SP. For example, the same voltage may be applied to the second electrodes CE2 of the plurality of sub-pixels and the cathode electrode 135 of the light-emitting element ED. Accordingly, the second electrode CE2 may be a common electrode. However, embodiments of the present disclosure are not limited thereto.

At least some of the plurality of sub-pixels may share the second electrode CE2 with each other. At least some of the second electrodes CE2 of the plurality of sub-pixels SP may be electrically connected to each other. As the same voltage is applied to the second electrodes CE2, the second electrode CE2 may be shared by the at least some sub-pixels. For example, the second electrodes CE2 of at least some pixels PX among the plurality of pixels PX disposed in the same row may be connected to each other. For example, one second electrode CE2 may be disposed in the plurality of pixels PX. One second electrode CE2 may be disposed in a combination of n sub-pixels.

In this regard, some of the respective second electrodes CE2 of the plurality of sub-pixels SP may be spaced apart or isolated from each other. For example, the second electrode CE2 connected to the pixels PX of an n-th row and the second electrode CE2 connected to the pixels PX of an (n+1)-th row may be spaced apart or isolated from each other. For example, adjacent ones of the plurality of second electrodes CE2 may be arranged to be spaced apart from each other while the plurality of communication lines NL extending in the row direction are disposed therebetween. Accordingly, the number of the plurality of sub-pixels may be greater than the number of the plurality of second electrodes CE2. In another example, all of the second electrodes CE2 of the plurality of sub-pixels may be connected to each other, such that only one second electrode CE2 may be disposed on the substrate 110. However, embodiments of the present disclosure are not limited thereto.

Each of the plurality of second electrodes CE2 may be made of a transparent conductive material. However, embodiments of the present disclosure are not limited thereto. Each of the plurality of second electrodes CE2 may be made of a transparent conductive material, and may allow light emitted from the light-emitting element ED to be directed upwardly of the second electrode CE2. For example, the second electrode CE2 may be made of a transparent conductive material such as Indium Tin Oxide (ITO), Indium Zinc Oxide (IZO), Indium Gallium Zinc Oxide (IGZO), etc. However, embodiments of the present disclosure are not limited thereto.

The plurality of contact electrodes CCE may be disposed on the substrate 110. For example, the plurality of contact electrodes CCE may be disposed to be spaced apart from the plurality of bank patterns BNK and the plurality of signal lines TL. Each of the plurality of second electrodes CE2 may overlap at least one contact electrode CCE. For example, one second electrode CE2 may overlap the plurality of contact electrodes CCE.

Each of the plurality of contact electrodes CCE may be electrically connected to each of the plurality of second electrodes CE2. Each of the plurality of contact electrodes CCE may be disposed between the substrate 110 and each of the plurality of second electrodes CE2 to transmit the cathode voltage from the pixel driving circuit PD to each of the second electrodes CE2.

Referring to FIG. 6, a black matrix BM is disposed on the plurality of second electrodes CE2. The black matrix BM may minimize the color mixing between light beams respectively emitted from the plurality of sub-pixels. The black matrix BM may be made of an opaque material. For example, the black matrix BM may be made of an organic insulating material to which a black pigment is added.

The black matrix BM includes a plurality of first transmission holes BMO1 and a plurality of second transmission holes BMO2.

The plurality of first transmission holes BMO1 are openings respectively overlapping the respective light-emitting elements ED of the plurality of sub-pixels. The light emitted from each of the plurality of light-emitting elements ED may be extracted out of the display device 1000 through each of the plurality of first transmission holes BMO1. The plurality of first transmission holes BMO1 may be disposed to respectively overlap some of the plurality of sub-pixels included in one pixel PX.

Each of the plurality of first transmission holes BMO1 may have a size larger than that of each of the plurality of light-emitting elements ED. For example, each of the plurality of first transmission holes BMO1 may be formed to be wider than a width of each of the plurality of light-emitting elements ED in a plan view of the display device, thereby securing a margin for a process deviation.

A shape in the plan view of each of the plurality of first transmission holes BMO1 may correspond to a shape in the plan view of each of the plurality of light-emitting elements ED. For example, when the shape in the plan view of each of the plurality of light-emitting elements ED is rectangular, the shape in the plan view of each of the plurality of first transmission holes BMO1 may be rectangular. However, the shape in the plan view of each of the plurality of first transmission holes BMO1 and the shape in the plan view of each of the plurality of light-emitting elements ED may be different from each other. However, embodiments of the present disclosures are not limited thereto.

The plurality of second transmission holes BMO2 are openings defined in an area between adjacent ones of the plurality of pixels PX. The plurality of communication lines NL extending in the row direction may be disposed in the area between adjacent ones of the plurality of pixels PX. In this regard, the plurality of second transmission holes BMO2 may be disposed to overlap at least some of the plurality of communication lines NL. Each of the plurality of second transmission holes BMO2 may be disposed in an area between adjacent ones of the plurality of second electrodes CE2. The plurality of communication lines NL may be used to perform short-range communication such as near field communication (NFC) using the plurality of second transmission holes BMO2.

A shape in the plan view of each of the plurality of second transmission holes BMO2 may be variously formed. For example, the shape in the plan view of each of the plurality of second transmission holes BMO2 may be a circular shape. For example, the shape in the plan view of each of the plurality of second transmission holes BMO2 may be a rectangular shape as the same shape in the plan view of the first transmission hole BMO1. The number and shape of the plurality of second transmission holes BMO2 may vary in consideration of signal transmission and reception. However, embodiments of the present disclosures are not limited thereto.

When the micro LED is used as the light-emitting element ED, a plurality of micro LEDs may be formed on a wafer, and the micro LEDs may be transferred to the substrate 110 of the display device 1000 to manufacture the display device 1000. However, various defects may occur in the process of transferring the plurality of light-emitting elements ED having a fine size from the wafer to the substrate 110. For example, a non-transfer defect in which the light-emitting element ED is not transferred may occur in some sub-pixels, and an incorrect position defect in which the light-emitting element ED is transferred out of the correct position due to an alignment error may occur in some further sub-pixels. In addition, the transfer process is normally performed, while the transferred light-emitting element ED itself may be defective. Therefore, the plurality of light-emitting elements ED of the same type may be transferred to one sub-pixel in consideration of the defect in the transfer process of the plurality of light-emitting elements ED. The lighting test of the plurality of light-emitting elements ED is performed, and only one light-emitting element ED that has been finally determined to be normal or non-defective may be used.

Accordingly, one of the pair of light-emitting elements ED may act as a main (primary) light-emitting element ED, and the other of the pair of light-emitting elements ED may act as a redundant light-emitting element ED. The redundant light-emitting element ED may be an extra light-emitting element ED that is transferred in preparation for the defect of the main light-emitting element ED. When the main light-emitting element ED is defective, the main light-emitting element ED may be replaced with the redundant light-emitting element ED. Accordingly, both the main light-emitting element ED and the redundant light-emitting element ED are transferred to one pixel PX at the same time, thereby minimizing a decrease in display quality due to the defect of the main light-emitting element ED and the redundant light-emitting element ED.

In addition, the plurality of first transmission holes BMO1 of the black matrix BM may be disposed based on whether the plurality of light-emitting elements ED are defective. Before the black matrix BM is formed, it may be checked whether the plurality of light-emitting elements ED are defective, and the plurality of first transmission holes BMO1 may be formed based on the checking result. The first transmission hole BMO1 may be disposed so as to overlap only one of the pair of first sub-pixels SP1. The first transmission hole BMO1 may be disposed so as to overlap only one of the pair of second sub-pixels SP2. The first transmission hole BMO1 may be disposed so as to overlap only one of the pair of third sub-pixels SP3. That is, one first transmission hole BMO1 may be formed only in one of the 1-1 sub-pixel SP1a and the 1-2 sub-pixel SP1b, one first transmission hole BMO1 may be formed only in one of the 2-1 sub-pixel SP2a and the 2-2 sub-pixel SP2b, and one first transmission hole BMO1 may be formed only in one of the 3-1 sub-pixel SP3a and the 3-2 sub-pixel SP3b.

However, in accordance with the present disclosure, an example in which the first transmission hole BMO1 is formed on only one of the main light-emitting element ED and the redundant light-emitting element ED and thus only one light-emitting element ED is used has been described. However, embodiments of the present disclosure are not limited thereto. For example, the first transmission hole BMO1 may be formed on each of both the main light-emitting element ED and the redundant light-emitting element ED to use both the main light-emitting element ED and the redundant light-emitting element ED.

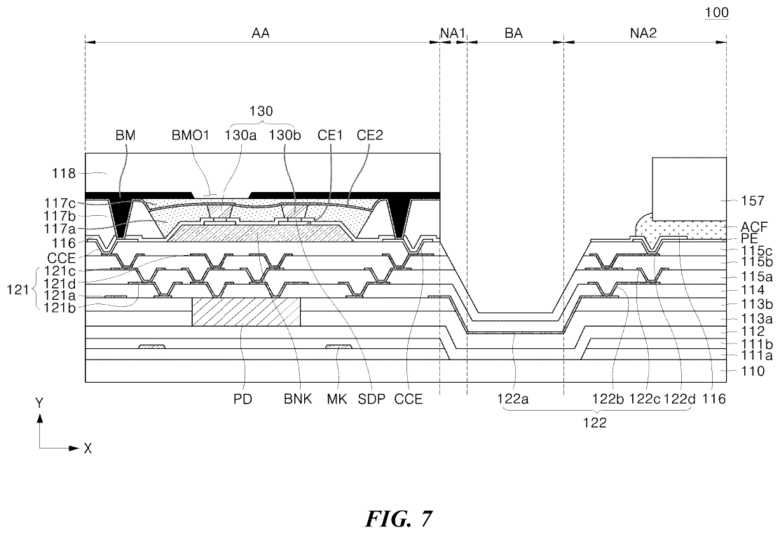

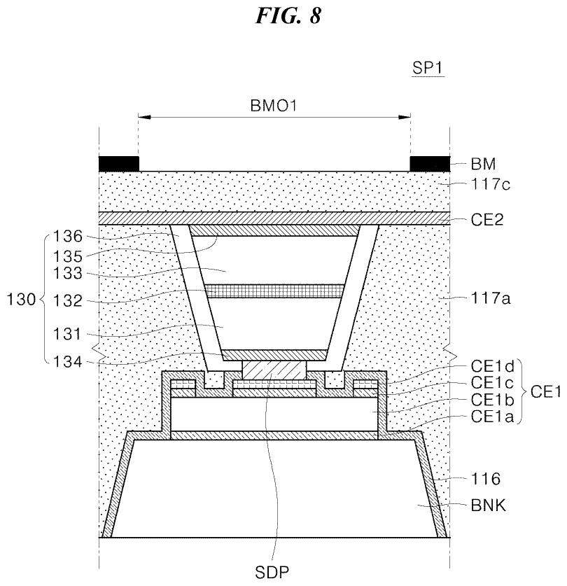

Hereinafter, a cross-sectional structure of a sub-pixel of the display device 1000 according to an embodiment of the present disclosure will be described with reference to FIGS. 7 and 8.

FIG. 7 is a cross-sectional view of a display device according to an embodiment of the present disclosure. FIG. 8 is a schematic enlarged cross-sectional view of a first sub-pixel of a display device according to an embodiment of the present disclosure. Specifically, FIG. 7 is a cross-sectional view of the display area AA, the first non-display area NA, the bending area BA, and the second non-display area NA2.

Referring to FIG. 7, a first buffer layer 111a and a second buffer layer 111b are disposed on a remaining area of the substrate 110 except for the bending area BA. The first buffer layer 111a and the second buffer layer 111b may be disposed in the display area AA, the first non-display area NA1, and the second non-display area NA2. The first buffer layer 111a and the second buffer layer 111b may reduce invasion of moisture or impurities through the substrate 110. Each of the first buffer layer 111a and the second buffer layer 111b may be made of an inorganic insulating material. For example, each of the first buffer layer 111a and the second buffer layer 111b may be formed as a single layer or multiple layers made of silicon oxide (SiOₓ) or silicon nitride (SiNₓ). However, embodiments of the present disclosure are not limited thereto.

In this regard, a portion of each of the first buffer layer 111a and the second buffer layer 111b in the bending area BA may be removed. An upper surface of a portion of the substrate 110 located in the bending area BA may be not covered with the first buffer layer 111a and the second buffer layer 111b so as to be exposed. Removing the portion of each of the first buffer layer 111a and the second buffer layer 111b made of the inorganic insulating material as disposed in the bending area BA may allow cracks of the first buffer layer 111a and the second buffer layer 111b that may occur during bending to be minimized.

A plurality of alignment keys MK may be disposed between the first buffer layer 111a and the second buffer layer 111b. The plurality of alignment keys MK may be configured to identify the position of the pixel driving circuit PD during the manufacturing process of the display device 1000. For example, the plurality of alignment keys MK may be configured to correctly align the positions of the pixel driving circuits PD transferred onto the adhesive layer 112. In another example, the plurality of alignment keys MK may be omitted.

The adhesive layer 112 may be disposed on the second buffer layer 111b. The adhesive layer 112 may be disposed in the display area AA, the first non-display area NA1, the bending area BA, and the second non-display area NA2. In another example, at least a portion of the adhesive layer 112 may be removed in the non-display area NA including the bending area BA. For example, the adhesive layer 112 may be made of one of an adhesive polymer, an epoxy resin, a UV curable resin, a polyimide-based resin, an acrylate-based resin, a urethane-based resin, and polydimethylsiloxane (PDMS). However, embodiments of the present disclosure are not limited thereto.

The pixel driving circuit PD may be disposed on the adhesive layer 112 and in the display area AA. When the pixel driving circuit PD is implemented as a driver, the driver may be mounted on the adhesive layer 112 in a transfer process. However, embodiments of the present disclosure are not limited thereto.

A first overcoat layer 113a and a second overcoat layer 113b may be disposed on the adhesive layer 112 and the pixel driving circuit PD. The first overcoat layer 113a and the second overcoat layer 113b may be disposed to surround a side surface of the pixel driving circuit PD. However, embodiments of the present disclosure are not limited thereto. For example, the second overcoat layer 113b may be disposed to cover at least a portion of an upper surface of the pixel driving circuit PD. For example, at least one of the first overcoat layer 113a and the second overcoat layer 113b disposed on the bending area BA may be omitted. For example, the first overcoat layer 113a may be entirely disposed in the display area AA and the non-display area NA, and the second overcoat layer 113b may be partially disposed in the display area AA, the first non-display area NA1, and the second non-display area NA2. For example, a portion of the second overcoat layer 113b in the bending area BA may be removed. However, embodiments of the present disclosure are not limited thereto.

Each of the first overcoat layer 113a and the second overcoat layer 113b may be made of an organic insulating material. However, embodiments of the present disclosure are not limited thereto. For example, each of the first overcoat layer 113a and the second overcoat layer 113b may be made of a photoresist, polyimide (PI), or an acryl-based material. However, embodiments of the present disclosure are not limited thereto.

According to the present disclosure, a plurality of first connection lines 121 may be disposed on the second overcoat layer 113b and in the display area AA. The plurality of first connection lines 121 may be lines for electrically connecting the pixel driving circuit PD to other components. For example, the pixel driving circuit PD may be electrically connected to the plurality of signal lines TL and the plurality of contact electrodes CCE via the plurality of first connection lines 121. For example, the plurality of first connection lines 121 may include a (1-1)-th connection line 121a, a (1-2)-th connection line 121b, a (1-3)-th connection line 121c, and a (1-4)-th connection line 121d. However, embodiments of the present disclosure are not limited thereto.

First, a plurality of (1-1)-th connection lines 121a may be disposed on the second overcoat layer 113b. The plurality of (1-1)-th connection lines 121a may be electrically connected to the pixel driving circuit PD. The plurality of (1-1)-th connection lines 121a may transmit a voltage output from the pixel driving circuit PD to the first electrode CE1 or the second electrode CE2.

Next, a protective layer 114 may be disposed on the second overcoat layer 113b. The protective layer 114 may be entirely disposed in the display area AA and the non-display area NA. In the bending area BA, the protective layer 114 may cover a side surface of the second overcoat layer 113b and an upper surface of the first overcoat layer 113a. The protective layer 114 may be made of an organic insulating material. For example, the protective layer 114 may be made of a photoresist, polyimide (PI), or an acryl-based material. However, embodiments of the present disclosure are not limited thereto.

A plurality of (1-2)-th connection lines 121b may be disposed on the protective layer 114. The plurality of (1-2)-th connection lines 121b may be indirectly connected to the pixel driving circuit PD or may be directly connected thereto. For example, some of the (1-2)-th connection lines 121b may be directly connected to the pixel driving circuit PD via a contact hole of the protective layer 114. The others of the (1-2)-th connection line 121b may be electrically connected to the (1-1)-th connection line 121a via a contact hole of the protective layer 114. However, embodiments of the present disclosure are not limited thereto. The voltage output from the pixel driving circuit PD may be transmitted to the first electrode CE1 or the second electrode CE2 via a connection line different from the plurality of (1-2)-th connection lines 121b.

A first organic insulating layer 115a may be disposed on the plurality of (1-2)-th connection lines 121b. The first organic insulating layer 115a may be entirely disposed in the display area AA and the non-display area NA. However, embodiments of the present disclosure are not limited thereto. The first organic insulating layer 115a may be made of an organic insulating material. However, embodiments of the present disclosure are not limited thereto. For example, the first organic insulating layer 115a may be made of a photo resist, polyimide (PI), or an acryl-based material. However, embodiments of the present disclosure are not limited thereto.

A plurality of (1-3)-th connection lines 121c may be disposed on the first organic insulating layer 115a. The plurality of (1-3)-th connection lines 121c may be electrically connected to the plurality of (1-2)-th connection lines 121b, respectively. For example, the (1-3)-th connection line 121c may be electrically connected to the (1-2)-th connection line 121a via a contact hole of the first organic insulating layer 115a.

A second organic insulating layer 115b may be disposed on the plurality of (1-3)-th connection lines 121c. The second organic insulating layer 115b may be disposed in the remaining area except for the bending area BA. However, embodiments of the present disclosure are not limited thereto. The second organic insulating layer 115b may be disposed in the display area AA, the first non-display area NA1, and the second non-display area NA2. However, embodiments of the present disclosure are not limited thereto. For example, a portion of the second organic insulating layer 115b disposed in the bending area BA may be removed. The second organic insulating layer 115b may be made of an organic insulating material. However, embodiments of the present disclosure are not limited thereto. For example, the second organic insulating layer 115b may be made of a photo resist, polyimide (PI), or an acryl-based material. However, embodiments of the present disclosure are not limited thereto.

A plurality of (1-4)-th connection lines 121d may be disposed on the second organic insulating layer 115b. The plurality of (1-4)-th connection lines 121d may be electrically connected to the plurality of (1-3)-th connection lines 121c, respectively. For example, the (1-4)-th connection line 121d may be electrically connected to the (1-3)-th connection line 121b via a contact hole of the second organic insulating layer 115b.

Next, a plurality of second connection lines 122 may be disposed on the second protective layer 113b and in the non-display area NA. The plurality of second connection lines 122 may be lines for transmitting signals transmitted from the flexible film 157 and the printed circuit board 160 (see FIG. 1) to the pad PAD to the pixel driving circuit PD of the display area AA. For example, the plurality of second connection lines 122 may be electrically connected to the plurality of pad electrodes PE respectively to receive signals from the flexible film 157 and the printed circuit board 160 (see FIG. 1).

Further, the plurality of second connection lines 122 may extend from the pad PAD toward the display area AA to transmit signals to the lines of the display area AA. In this case, the plurality of second connection lines 122 may function as link lines LL (see FIG. 2). The plurality of second connection lines 122 may include a (2-1)-th connection line 122a, a (2-2)-th connection line 122b, a (2-3)-th connection line 122c, and a (2-4)-th connection line 122d.

A plurality of (2-1)-th connection lines 122a may be disposed on the second protective layer 113b. The plurality of (2-1)-th connection lines 122a may extend from the second non-display area NA2 to the bending area BA and the first non-display area NA1. The plurality of (2-1)-th connection lines 122a may transmit signals transmitted from the flexible film 157 and the printed circuit board 160 (see FIG. 1) to the pad PAD to the pixel driving circuit PD of the display area AA.

A plurality of (2-2)-th connection lines 122b may be disposed on the protective layer 114. The plurality of (2-2)-th connection lines 122b may be disposed in the second non-display area NA2. The (2-2)-th connection line 122b may be electrically connected to the (2-1)-th connection line 122a via a contact hole of the protective layer 114. Accordingly, signals from the flexible film 157 and the printed circuit board 160 (see FIG. 1) may be transmitted to the (2-1)-th connection line 122b via the (2-1)-th connection line 122a.

The (2-3)-th connection line 122c may be disposed on the first organic insulating layer 115a. The (2-3)-th connection line 122c may be disposed in the second non-display area NA2. The (2-3)-th connection line 122c may be electrically connected to the (2-2)-th connection line 122a via a contact hole of the first organic insulating layer 115b. Accordingly, signals from the flexible film 157 and the printed circuit board 160 (see FIG. 1) may be transmitted to the (2-1)-th connection line 122a via the (2-3)-th connection line 122c and the (2-2)-th connection line 122b.

The (2-4)-th connection line 122d may be disposed on the second organic insulating layer 115b. The (2-4)-th connection line 122d may be disposed in the second non-display area NA2. The (2-4)-th connection line 122d may be electrically connected to the (2-3)-th connection line 122b via a contact hole of the second organic insulating layer 115c. Accordingly, signals from the flexible film FF and the printed circuit board may be transmitted to the (2-1)-th connection line 122a via the (2-4)-th connection line 122d, the (2-3)-th connection line 122c, and the (2-2)-th connection line 122b.

Each of the plurality of first connection lines 121 and the plurality of second connection lines 122 may be made of a conductive material having excellent ductility or various conductive materials used in the display area AA. For example, the second connection line 122, a portion of which is disposed in the bending area BA, may be made of a conductive material having excellent ductility, such as gold (Au), silver (Ag), or aluminum (Al). However, embodiments of the present disclosure are not limited thereto. In another example, each of the plurality of first connection lines 121 and the plurality of second connection lines 122 may be made of molybdenum (Mo), chromium (Cr), titanium (Ti), nickel (Ni), neodymium (Nd), copper (Cu), an alloy of silver (Ag) and magnesium (Mg), or an alloy thereof. However, embodiments of the present disclosure are not limited thereto.

A third organic insulating layer 115c may be disposed on the plurality of first connection lines 121 and the plurality of second connection lines 122. The third organic insulating layer 115c may be disposed in the remaining area except for the bending area BA. However, embodiments of the present disclosure are not limited thereto. The third organic insulating layer 115c may be disposed in the display area AA, the first non-display area NA1, and the second non-display area NA2. A portion of the third organic insulating layer 115c in the bending area BA may be removed. The third organic insulating layer 115c may be made of an organic insulating material. However, embodiments of the present disclosure are not limited thereto. For example, the third organic insulating layer 115c may be made of a photo resist, polyimide (PI), or an acryl-based material. However, embodiments of the present disclosure are not limited thereto.

In the display area AA, a plurality of bank patterns BNK may be disposed on the third organic insulating layer 115c. The plurality of bank patterns BNK may be disposed to overlap the plurality of sub-pixels, respectively. One or more light-emitting elements ED of the same type may be disposed on each of the plurality of bank patterns BNK. For example, the first light-emitting element 130 including the (1-1)-th light-emitting element 130a and the (1-2)-th light-emitting element 130b emitting light of the same color may be disposed on one bank pattern BNK. Although the first light-emitting element 130 is illustrated in FIG. 7 for convenience of illustration, each of the second light-emitting element 140 and the third light-emitting element 150 may also have substantially the same structure as that of the first light-emitting element 130.

In the display area AA, the plurality of signal lines TL may be disposed on the third organic insulating layer 115c. The plurality of signal lines TL may be disposed in an area between adjacent ones of the plurality of bank patterns BNK. For example, the plurality of signal lines TL may be disposed adjacent to one of the plurality of bank patterns BNK.

The plurality of contact electrodes CCE may be disposed on the third organic insulating layer 115c in the display area AA. The plurality of contact electrodes CCE may supply the cathode voltage from the pixel driving circuit PD to the second electrode CE2.

The first electrode CE1 may be disposed on the bank pattern BNK. For example, the first electrode CE1 may be disposed to extend from the adjacent signal line TL toward the upper portion of the bank pattern BNK. The first electrode CE1 may be disposed on an upper surface of the bank pattern BNK and a side surface of the bank pattern BNK. For example, the first electrode CE1 may be disposed to extend from the signal line TL on the upper surface of the third organic insulating layer 115c to the side surface of the bank pattern BNK and the upper surface of the bank pattern BNK.

Referring to FIG. 8, the first electrode CE1 may be made of a plurality of conductive layers.

For example, the first electrode CE1 may include a first conductive layer CE1a on the bank pattern BNK, a second conductive layer CE1b on the first conductive layer CE1a, a third conductive layer CE1c on the second conductive layer CE1b, and a fourth conductive layer CE1d on the third conductive layer CE1c. Each of the first conductive layer CE1a, the second conductive layer CE1b, the third conductive layer CE1c, and the fourth conductive layer CE1d may include titanium (Ti), aluminum (Al), titanium (Ti), and indium tin oxide (ITO).

In this regard, some conductive layers having good reflection efficiency among the plurality of conductive layers constituting the first electrode CE1 may act as an alignment key for aligning the light-emitting element ED and/or a reflective plate. For example, the second conductive layer CE1b of the plurality of conductive layers of the first electrode CE1 may include a reflective material. For example, the second conductive layer CE1b may include aluminum (Al). However, embodiments of the present disclosure are not limited thereto. Accordingly, the second conductive layer CE1b may act as the reflective plate. In addition, due to the high reflection efficiency of the second conductive layer CE1b, the second conductive layer CE1b may be easily identified in the manufacturing process, and thus the position of the light-emitting element ED or the transfer position may be aligned with the second conductive layer CE1b.

Further, in order that the second conductive layer CE1b acts as the reflective plate, a portion of each of the third conductive layer CE1c and the fourth conductive layer CE1d covering the second conductive layer CEb may be removed or etched. For example, an upper surface of the second conductive layer CE1b may be exposed by removing or etching the portion of each of the third conductive layer CE1c and the fourth conductive layer CE1d disposed on the bank BNK. For example, a central portion and an edge portion of each of the third conductive layer CE1c and the fourth conductive layer CE1d on which a solder pattern SDP is disposed, may be left, and the remaining portion other than the central portion and the edge portion thereof may be removed. For example, the edge portion of each of the third conductive layer CE1c made of titanium (Ti) and the fourth conductive layer CE1d made of indium tin oxide (ITO) may not be etched. This may prevent the other conductive layers of the first electrode CE1 from being corroded by a tetraMethylammoniumhydroxide (TMAH) solution used in a mask process.

According to the present disclosure, each of the signal line TL, the contact electrode CCE, and the pad electrode PE which are disposed at the same layer as a layer of the first electrode CE1, may be composed of multiple layers of a conductive material. However, embodiments of the present disclosure are not limited thereto. For example, each of the signal line TL, the contact electrode CCE, and the pad electrode PE may be composed of a multi-layers structure of titanium (Ti) layer/aluminum (Al) layer/titanium (Ti) layer/indium tin oxide (ITO) layer. However, embodiments of the present disclosures are not limited thereto.

Next, in each of the plurality of sub-pixels, the solder pattern SDP is disposed on the first electrode CE1. The solder pattern SDP may be used to bond the light-emitting element ED to the first electrode CE1. The first electrode CE1 and the light-emitting element ED may be electrically connected to each other via eutectic bonding using the solder pattern SDP. However, embodiments of the present disclosure are not limited thereto. For example, when the solder pattern SDP is made of indium (In) and the anode electrode 134 of the light-emitting element ED is made of gold (Au), heat and pressure may be applied thereto in the transfer process of the light-emitting element ED to bond the solder pattern SDP and the anode electrode 134 to each other. Via the eutectic bonding, the light-emitting element ED may be bonded to the solder pattern SDP and the first electrode CE1 without a separate adhesive. For example, the solder pattern SDP may be made of indium (In), tin (Sn), or an alloy thereof. However, embodiments of the present disclosure are not limited thereto.

A passivation layer 116 may be disposed on the plurality of signal lines TL, the plurality of first electrodes CE1, the plurality of contact electrodes CCE, and the third organic insulating layer 115c. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE in the second non-display area NA2 may be removed. Since the passivation layer 116 is disposed to cover the remaining area except for the bending area BA, an area of the plurality of pad electrodes PE, and an area of the solder pattern SDP, penetration of moisture or impurities flowing into the light-emitting element ED may be reduced. For example, the passivation layer 116 may be formed as a single layer or multiple layers made of silicon oxide (SiOₓ) or silicon nitride (SiNₓ). However, embodiments of the present disclosure are not limited thereto.

In each of the plurality of sub-pixels, the light-emitting element ED is disposed on the solder pattern SDP. The first light-emitting element 130 may be disposed in the first sub-pixel SP1, the second light-emitting element 140 may be disposed in the second sub-pixel SP2, and the third light-emitting element 150 may be disposed in the third sub-pixel SP3.

Referring to FIG. 8, the first light-emitting element 130 includes an anode electrode 134, a first semiconductor layer 131, a light-emitting layer 132, a second semiconductor layer 133, a cathode electrode 135, and an encapsulation film 136.

First, the first semiconductor layer 131 is disposed on the solder pattern SDP, and the second semiconductor layer 133 is disposed on the first semiconductor layer 131. One of the first semiconductor layer 131 and the second semiconductor layer 133 may be made of a semiconductor layer doped with n-type impurities, and the other thereof may be made of a semiconductor layer doped with p-type impurities. However, embodiments of the present disclosure are not limited thereto. For example, each of the first semiconductor layer 131 and the second semiconductor layer 133 may be a layer in which n-type or p-type impurities are doped into a material such as gallium nitride (GaN), indium aluminum phosphide (InAlP), gallium arsenide (GaAs), or the like. The n-type impurity may include silicon (Si), germanium (Ge), tin (Sn), or the like, and the p-type impurity may include magnesium, zinc (Zn), beryllium (Be), or the like. However, embodiments of the present disclosure are not limited thereto.

The light-emitting layer 132 is disposed between the first semiconductor layer 131 and the second semiconductor layer 133. The light-emitting layer 132 may receive holes and electrons from the first semiconductor layer 131 and the second semiconductor layer 133 to emit light. For example, the active layer 132 may be composed of one of a single well structure, a multiple well structure, a single quantum well structure, a multi-quantum well (MQW) structure, a quantum dot structure, and a quantum wire structure. However, embodiments of the present disclosure are not limited thereto. For example, the active layer 132 may be made of indium gallium nitride (InGaN) or gallium nitride (GaN). However, embodiments of the present disclosure are not limited thereto.

The anode electrode 134 is disposed between the first semiconductor layer 131 and the solder pattern SDP. The anode electrode 134 is an electrode for electrically connecting the first semiconductor layer 131 and the first electrode CE1 to each other. An anode voltage output from the pixel driving circuit PD may be applied to the first semiconductor layer 131 via the signal line TL, the first electrode CE1, and the anode electrode 134. The anode electrode 134 may be made of a conductive material capable of eutectic bonding with the solder pattern SDP. For example, the anode electrode 134 may be made of gold (Au), tin (Sn), indium (In), zinc (Zn), lead (Pb), nickel (Ni), platinum (Pt), copper (Cu), or the like. However, embodiments of the present disclosure are not limited thereto.

The cathode electrode 135 is disposed on the second semiconductor layer 133. The cathode electrode 135 is an electrode for electrically connecting the second semiconductor layer 133 and the second electrode CE2 to each other. A cathode voltage output from the pixel driving circuit PD may be applied to the second semiconductor layer 133 via the contact electrode CCE, the second electrode CE2, and the cathode electrode 135. The cathode electrode 135 may be made of a transparent conductive material so that light emitted from the light-emitting element ED may be directed upwardly of the light-emitting element ED. For example, the cathode electrode 135 may be made of a transparent conductive material such as Indium Tin Oxide (ITO), Indium Zinc Oxide (IZO), Indium Gallium Zinc Oxide (IGZO), or the like. However, embodiments of the present disclosure are not limited thereto.

The encapsulation film 136 may be disposed on at least a portion of each of the first semiconductor layer 131, the active layer 132, the second semiconductor layer 133, the anode electrode 134, and the cathode electrode 135. For example, the encapsulation film 136 may surround at least a portion of each of the first semiconductor layer 131, the active layer 132, the second semiconductor layer 133, the anode electrode 134, and the cathode electrode 135. For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133. For example, the encapsulation film 136 may be disposed on at least a portion of each of the anode electrode 134 and the cathode electrode 135, for example, an edge portion (or one side surface) of the anode electrode 134 and an edge portion (or one side surface) of the cathode electrode 135. At least a portion of the anode electrode 134 may not be covered with the encapsulation film 136 such that the anode electrode 134 and the solder pattern SDP are connected to each other. For example, at least a portion of the cathode electrode 135 may not be covered with the encapsulation film 136 such that the cathode electrode 135 and the second electrode CE2 are connected to each other. For example, the encapsulation film 136 may be made of an insulating material such as silicon nitride (SiNₓ) or silicon oxide (SiOₓ). However, embodiments of the present disclosure are not limited thereto.

Although the first light-emitting element 130 has been described with reference to FIG. 8, each of the second light-emitting element 140 and the third light-emitting element 150 may have substantially the same structure as that of the first light-emitting element 130. For example, the first semiconductor layer, the active layer, the second semiconductor layer, the anode electrode, the cathode electrode, and the encapsulation film of each of the second light-emitting element 140 and the third light-emitting element 150 may be substantially the same as the first semiconductor layer 131, the active layer 132, the second semiconductor layer 133, the anode electrode 134, the cathode electrode 135, and the encapsulation film 136 of the first light-emitting element 130, respectively.

Next, referring to FIGS. 3, 4, and 7 together, the first optical layer 117a surrounding the first light-emitting element 130 is disposed in the display area AA. The first optical layer 117a may be disposed to cover the first light-emitting element 130 and the bank pattern BNK in the areas of the plurality of sub-pixels. For example, one pixel PX may include the first light-emitting element 130, the second light-emitting element 140, and the third light-emitting element 150. The first optical layer 117a may be disposed between adjacent ones of the first light-emitting element 130, the second light-emitting element 140, and the third light-emitting element 150 included in one pixel PX. In addition, the first optical layer 117a may be disposed between adjacent ones of the plurality of bank patterns BNK that distinguish the first light-emitting element 130, the second light-emitting element 140, and the third light-emitting element 150 from each other. The first optical layer 117a may be disposed between the passivation layer 116 and the second electrode CE2 so as to surround the side surface of each of the first light-emitting element 130 and the bank pattern BNK. The first optical layer 117a may be disposed to surround the bank pattern BNK and the first light-emitting elements 130 disposed on the bank pattern BNK and arranged in the X-direction. For example, a width of the first optical layer 117a may increase as the first optical layer 117a extends from a bottom to a top thereof. Accordingly, an area size of an upper surface of the first optical layer 117a may be greater than an area size of a lower surface thereof. For example, an area size of a lower surface of the bank pattern BNK may be greater than an area size of a lower surface thereof. The first optical layer 117a may have an inverted tapered shape in a cross-sectional view. The upper surface and the lower surface of the first optical layer 117a having the inverted tapered shape may be connected to each other via an inclined side surface.

The area size of the upper surface of the first optical layer having the tapered shape is smaller than the area size of the lower surface thereof. The first optical layer having the tapered shape may exhibit a relatively lower light extraction efficiency than the light extraction efficiency which the first optical layer 117a having the inverted tapered shape exhibits. Accordingly, the first optical layer 117a according to an embodiment of the present disclosure may have the inverted tapered shape.

The first optical layer 117a may be made of an organic insulating material in which light scattering particles are dispersed. For example, the first optical layer 117a may be made of siloxane in which fine metal particles such as titanium dioxide (TiO₂) particles are dispersed. However, embodiments of the present disclosure are not limited thereto. Light from the plurality of light-emitting elements ED may be scattered by the fine particles dispersed in the first optical layer 117a so as to be emitted to the outside. The first optical layer 117a may improve extraction efficiency of the light emitted from the plurality of light-emitting elements ED.

In this case, the first optical layer 117a may be disposed in each of the plurality of pixels PX, or may be commonly disposed in a combination of some pixels PX arranged in the same row. That is, the first optical layer 117a may be disposed in each of the plurality of pixels PX, or the plurality of pixels PX may share one first optical layer 117a with each other. In addition, each of the plurality of sub-pixels SP may separately include the first optical layer 117a. However, embodiments of the present disclosure are not limited thereto.

The second optical layer 117b is disposed on the passivation layer 116 and in the display area AA. The second optical layer 117b may be disposed on an outer side of the first optical layer 117a. For example, the second optical layer 117b may be disposed to surround the first optical layer 117a. The second optical layer 117b may be in contact with the side surface of the first optical layer 117a. The second optical layer 117b may be disposed in an area between adjacent ones of the plurality of pixels PX.

The second optical layer 117b may be made of an organic insulating material. The second optical layer 117b may be made of the same organic insulating material as that of the first optical layer 117a. The first optical layer 117a may include light scattering particles, while the second optical layer 117b may not include light scattering particles. For example, the second optical layer 117b may be made of siloxane. However, embodiments of the present disclosure are not limited thereto.

In a cross-sectional view, the first optical layer 117a may have an inverted tapered shape in which the width of the upper surface thereof is larger than the width of the lower surface thereof. For example, as the bank pattern BNK is disposed under the first optical layer 117a, the width of the upper surface of the first optical layer 117a may be larger than the width of the lower surface of the bank pattern BNK.

When the first optical layer 117a has the tapered shape, the width of the upper portion of the first optical layer 117a may be smaller than the width of the lower portion thereof. As the width of the upper surface of the first optical layer 117a is smaller, a distance between the second optical layer 117b and the light-emitting element ED may decrease.

The first optical layer 117a is made of an organic insulating material in which light scattering particles are dispersed. As an amount by which the light emitted from the light-emitting element ED is incident onto the first optical layer 117a increases, an amount of the light scattered by the light scattering particles so as to be emitted to the outside may increase. That is, as the amount of the light scattered by the light scattering particles increases, the light extraction efficiency may increase. Accordingly, as the amount by which the light is incident from the light-emitting element ED to the first optical layer 117a increases, the light extraction efficiency may increase.

Otherwise, when the first optical layer 117a has not the inverted tapered shape but the taped shape, and thus the distance between the second optical layer 117b and the light-emitting element ED decreases, a portion of the light emitted from the light-emitting element ED may be incident on the second optical layer 117b. In this regard, the second optical layer 117b does not contain the light scattering particles. Thus, the amount of light incident on the second optical layer 117b increases, the light extraction efficiency may be reduced. Accordingly, it is preferable that the first optical layer 117a has the inverted tapered shape in the cross-sectional view thereof.

According to an embodiment of the present disclosure, as the first optical layer 117a has the inverted tapered shape, the amount by which the light is incident from the light-emitting element ED to the first optical layer 117a increases, and thus the light extraction efficiency may increase. Accordingly, the display device capable of operating at a low power level to reduce power consumption may be realized.

The second electrode CE2 is disposed on the first optical layer 117a and the second optical layer 117b. The second electrode CE2 may be electrically connected to the plurality of contact electrodes CCE via a contact hole of the second optical layer 117b.

The third optical layer 117c is disposed on the second electrode CE2. The third optical layer 117c may be disposed to overlap the plurality of light-emitting elements ED and the first optical layer 117a. The third optical layer 117c may be disposed on the second electrode CE2 and the plurality of light-emitting elements ED to suppress mura caused by some of the plurality of light-emitting elements ED. Specifically, when the plurality of light-emitting elements ED are transferred onto the substrate 110 of the display device 1000, an area in which spacings between adjacent ones of the plurality of light-emitting elements ED are not uniform may occur due to process variations or etc. When the spacings between adjacent ones of the plurality of light-emitting elements ED are non-uniform, respective light emission areas of the plurality of light-emitting elements ED may be non-uniformly arranged, and thus, the mura may be visually recognized by the user. Accordingly, since the third optical layer 117c configured to uniformly diffuse light is formed on top of the plurality of light-emitting elements ED, a phenomenon that the light emitted from some light-emitting elements ED is visible as the mura to the user may be suppressed. Accordingly, the light emitted from the plurality of light-emitting elements ED may be uniformly diffused by the third optical layer 117c and then be extracted out of the display device 1000, such that the luminance uniformity of the display device 1000 may be improved.

The third optical layer 117c may be made of an organic insulating material in which light scattering particles are dispersed. For example, the third optical layer 117c may be made of siloxane in which fine metal particles such as titanium dioxide (TiO₂) particles are dispersed. However, embodiments of the present disclosure are not limited thereto. Light from the plurality of light-emitting elements ED may be scattered by the fine particles dispersed in the third optical layer 117c so as to be emitted to the outside. The third optical layer 117c may evenly mix light beams respectively emitted from the plurality of light-emitting elements ED with each other to further improve luminance uniformity of the display device 1000. In addition, light extraction efficiency of the display device 1000 may be improved by the light being scattered from the plurality of fine particles, and accordingly, the display device 1000 may operate at a low power level.

In the display area AA, the black matrix BM is disposed on the second electrode CE2, the first optical layer 117a, the second optical layer 117b, and the third optical layer 117c. The black matrix BM is constructed to cover the display area AA, thereby reducing color mixture between light beams from the plurality of sub-pixels and external light reflection. In addition, the black matrix BM may be disposed in a contact hole via which the second electrode CE2 and the contact electrode CCE are connected to each other, thereby preventing light leakage. The black matrix BM may be disposed to overlap at least one light-emitting element ED. For example, referring to FIG. 7, the black matrix BM may be disposed to overlap the (1-2)-th light-emitting element 130b.

A cover layer 118 is disposed on the black matrix BM and in the display area AA. The cover layer 118 may protect the components under the cover layer 118. For example, the cover layer 118 may be made of an organic insulating material. However, embodiments of the present disclosure are not limited thereto. For example, the cover layer 118 may be made of a photoresist, polyimide (PI), or an acryl-based material. However, embodiments of the present disclosure are not limited thereto.

The plurality of pad electrodes PE are disposed on the third organic insulating layer 115c and in the second non-display area NA2. At least a portion of each of the plurality of pad electrodes PE may not be covered with the passivation layer 116 so as to be exposed. For example, the plurality of pad electrodes PE may be electrically connected to the (2-4)-th connection line 122d via a contact hole of the third insulating layer 115c.

A conductive adhesive layer ACF is disposed on the plurality of pad electrodes PE. The conductive adhesive layer ACF may be an adhesive layer in which conductive balls are dispersed in an insulating material. However, embodiments of the present disclosure are not limited thereto. When heat or pressure is applied to the adhesive layer ACF, the conductive balls may be electrically connected to each other in an area to which the heat or pressure has been applied such that the adhesive layer ACF may be conductive. The adhesive layer ACF may be disposed between the plurality of pad electrodes PE and the flexible film 157 to attach or bond the flexible film 157 to the plurality of pad electrodes PE. For example, the adhesive layer ACF may be embodied as an anisotropic conductive film (ACF). However, embodiments of the present disclosure are not limited thereto.

The flexible film 157 is disposed on the conductive adhesive layer ACF. The flexible film 157 may be electrically connected to the plurality of pad electrodes PE via the conductive adhesive layer ACF. Accordingly, signals output from the flexible film 157 and the printed circuit board 160 (see FIG. 1) may be transmitted to the pixel driving circuit PD of the display area AA via the plurality of pad electrodes PE, the (2-4)-th connection line 122d, the (2-3)-th connection line 122c, the (2-1)-th connection line 122b, and the (2-1)-th connection line 122a.

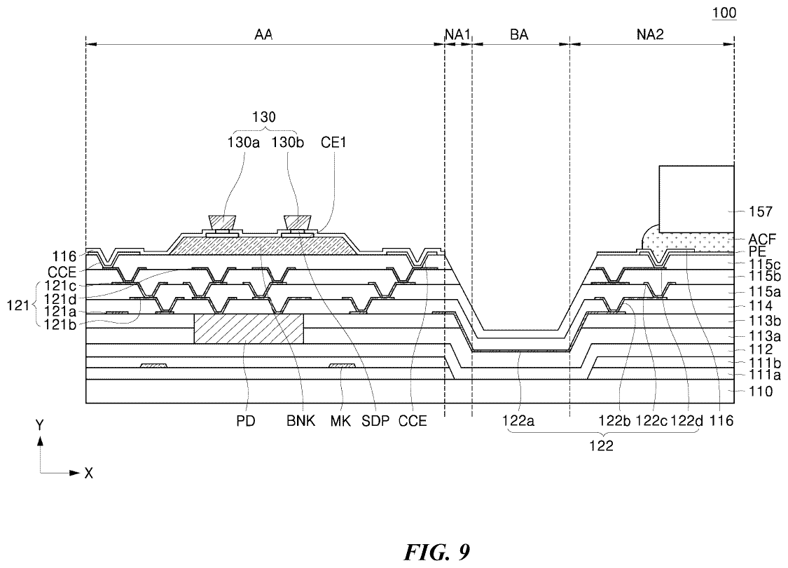

FIGS. 9 to 14 are diagrams illustrating a method for manufacturing a display device according to an embodiment of the present disclosure.

In FIG. 9 to FIG. 14, descriptions of contents duplicate with those as described with reference to FIG. 7 and FIG. 8 will be omitted.

First, referring to FIG. 9, the first light-emitting element 130 may be disposed on the bank pattern BNK disposed on the third organic insulating layer 115c. Although the first light-emitting element 130 is illustrated in FIG. 8, the illustration may be applied to the second light-emitting element 140 or the third light-emitting element 150. The first light-emitting element 130 may include the (1-1)-th light-emitting element 130a and the (1-2)-th light-emitting element 130b.

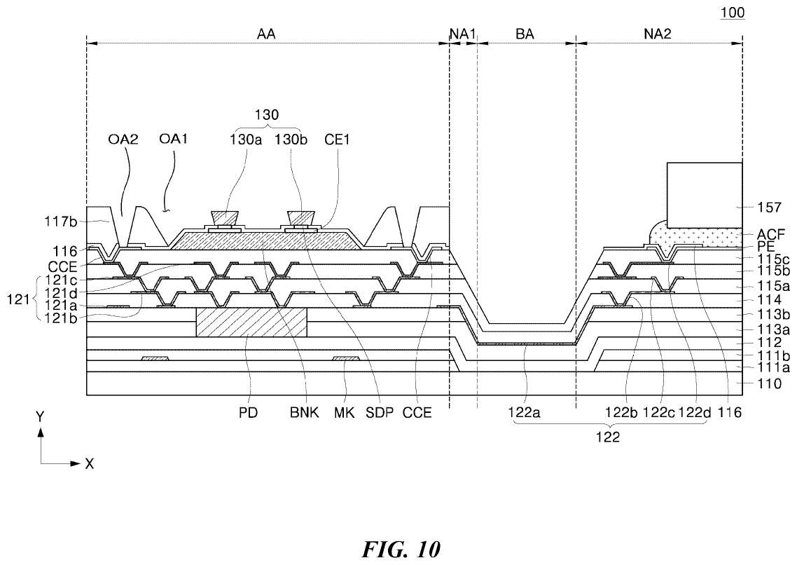

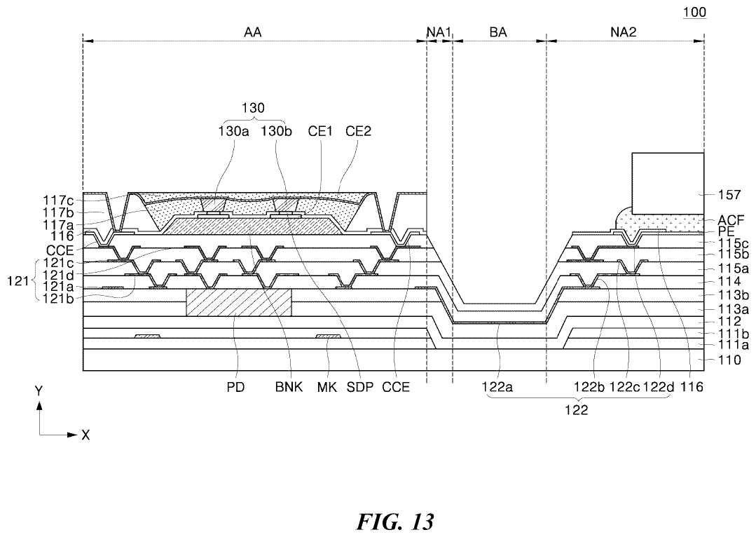

Referring to FIG. 10, the second optical layer 117b may be disposed on the third organic insulating layer 115c so as to be patterned. The second optical layer 117b may be disposed in an area other than an area (see FIG. 13) in which the bank pattern BNK and the black matrix BM contact the contact electrode CCE. For example, the second optical layer 117b may include a first open area OA1 and a second open area OA2 defined therein. The first open area OA 1 may overlap an area in which the bank pattern BNK is disposed. The second open area OA 2 may be an area in which the black matrix BM is to be disposed in a subsequent process, and may expose a portion of a surface of the contact electrode CCE. The second open area OA 2 may be referred to as a contact hole area. A width of the first open area OA1 may become smaller as the first open area extends downwardly. A width of the second open area OA2 may become smaller as the second open area extends downwardly.

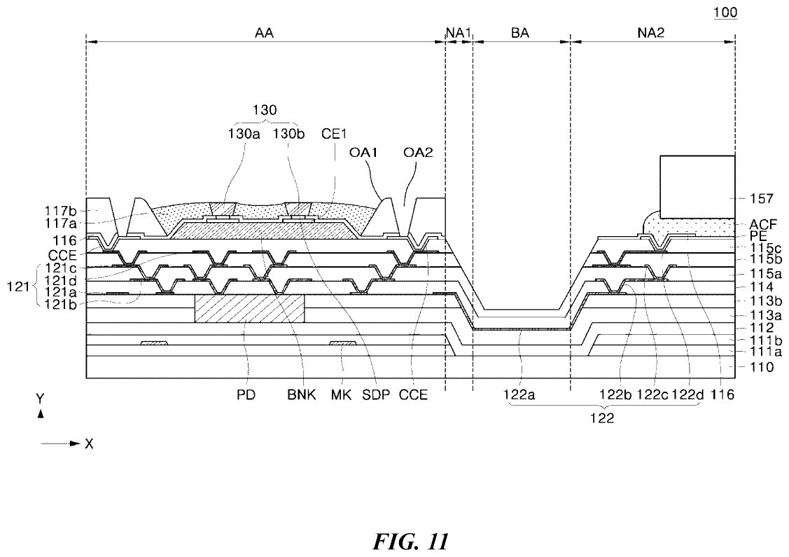

Referring to FIG. 11, the first optical layer 117a may be disposed on the bank pattern BNK. The first optical layer 117a may fill the first open area OA1. For example, the first optical layer 117a may be disposed on the bank pattern BNK and on the side surface of the first light-emitting element 130. The first optical layer 117a may be formed in the inverted tapered shape. That is, the area size of the upper surface of the first optical layer 117a may be greater than the area size of the lower surface of the bank pattern BNK. For example, the upper surface of the first optical layer 117a may be disposed at a position relatively lower than a position of the upper surface of the second optical layer 117b.

The first optical layer 117a may be made of an organic insulating material in which light scattering particles are dispersed. For example, the first optical layer 117a may be made of siloxane in which fine metal particles such as titanium dioxide (TiO₂) particles are dispersed. However, embodiments of the present disclosure are not limited thereto. Light from the plurality of light-emitting elements ED may be scattered by the light scattering particles dispersed in the first optical layer 117a so as to be emitted to the outside. Accordingly, the first optical layer 117a may improve extraction efficiency of the light emitted from the first light-emitting element 130.

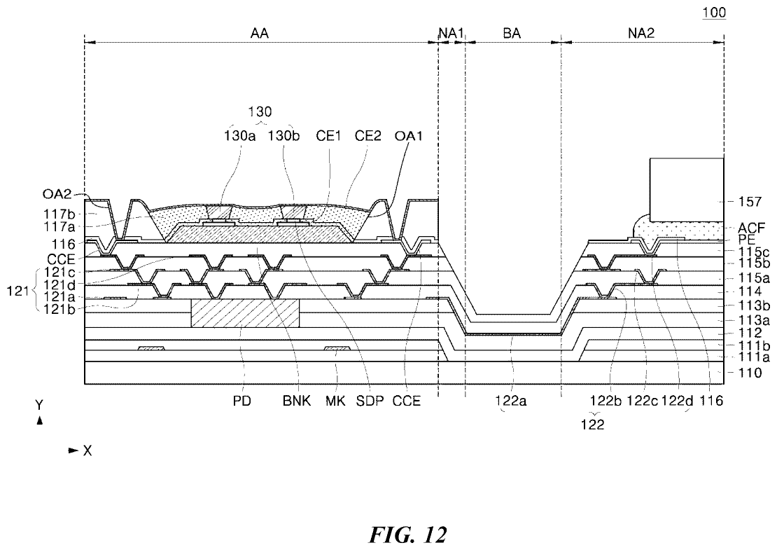

Referring to FIG. 12, the second electrode CE2 may be disposed on the first optical layer 117a, the second optical layer 117b, and the first light-emitting element 130. The second electrode CE2 may be connected to the contact electrode CCE in the second open area OA2 as the contact hole area of the second optical layer 117b. The second electrode CE2 may continuously extend from the first open area OA 1 to the second open area OA 2 without breakage thereof.

Referring to FIG. 13, the third optical layer 117c may be disposed on the second electrode CE2. The third optical layer 117c may be disposed to overlap the bank pattern BNK, the first optical layer 117a, and the first light-emitting element 130.

The third optical layer 117c may be the same material as that of the first optical layer 117a and may be made of an organic insulating material in which light scattering particles are dispersed. The third optical layer 117c may be disposed to have a maximum thickness of 1 um. The third optical layer 117c may extend to an area adjacent to an outer edge of the display panel while having a maximum thickness of 0.3 um, thereby improving the extraction efficiency of light throughout the display panel. For example, the display panel may include the substrate 110 including the display area AA and the non-display area NA. The area adjacent to the outer edge of the display panel may be located between the display area AA and the first non-display area NA1.

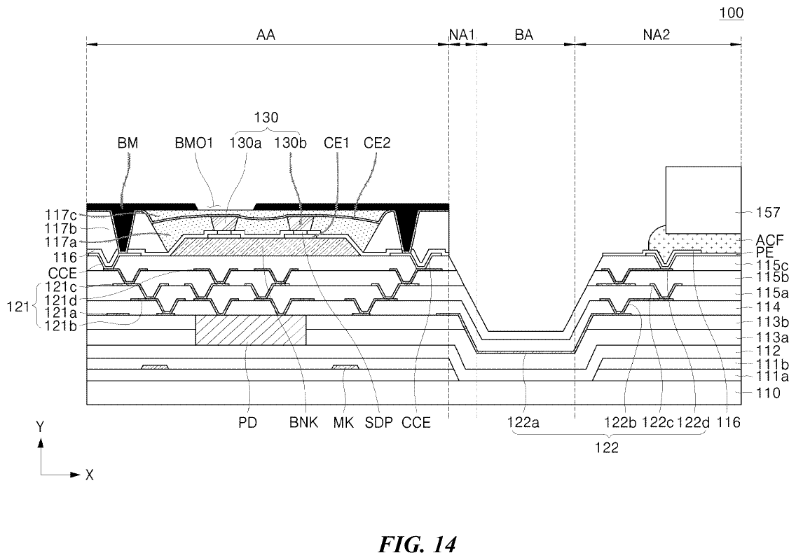

Referring to FIG. 14, the black matrix BM may be disposed on the second electrode CE2, the first optical layer 117a, the second optical layer 117b, and the third optical layer 117c. The black matrix BM may also be disposed in the contact hole via which the second electrode CE2 and the contact electrode CCE are connected to each other, thereby preventing light leakage. The black matrix BM may include the first opening hole BMO1 defining the light emission area. The first opening hole BMO1 may expose one light-emitting element ED determined to be non-defective among the pair of light-emitting elements ED disposed in one sub-pixel. The black matrix BM may be disposed to overlap at least one first light-emitting element 130. For example, one first sub-pixel SP1 in which the (1-1)-th light-emitting element 130a and the (1-2)-th light-emitting element 130b are disposed may be inspected to determine whether each of the (1-1)-th light-emitting element 130a and the (1-2)-th light-emitting element 130b is defective. When both the (1-1)-th light-emitting element 130a and the (1-2)-th light-emitting element 130b are determined to be non-defective in the defect inspection, the first opening hole BMO1 may overlap the (1-1)-th light-emitting element 130a as the main light-emitting element, while the (1-2)-th light-emitting element 130b may be covered with the black matrix BM. For example, referring to FIG. 13, the black matrix BM may be disposed to overlap the (1-2)-th light-emitting element 130b as the redundant light-emitting element. Accordingly, the (1-2)-th light-emitting element 130b may be covered with the black matrix BM and may not be exposed to the outside. Each of the second light-emitting element 140 and the third light-emitting element 150 may also be inspected to determine whether each of the two light-emitting elements disposed therein is defective. Then, at least one of the two light-emitting elements disposed therein may be covered with the black matrix BM based on the inspection result.

The display device according to various aspects and embodiments of the present disclosure may be described as follows.

A first aspect of the present disclosure provides a display device comprising: a substrate; at least one pixel driving circuit disposed on the substrate; a plurality of bank patterns disposed on the pixel driving circuit; a plurality of light-emitting elements disposed on each of the plurality of bank patterns and electrically connected to the pixel driving circuit; at least one optical layer disposed to surround the plurality of light-emitting elements; and a black matrix disposed on the optical layer and overlapping at least one of the light-emitting elements, wherein the at least one optical layer includes a first optical layer, a second optical layer, and a third optical layer.

In accordance with some embodiments of the first aspect of the present disclosure, the display device further comprises: a plurality of first electrodes respectively disposed between each of the plurality of bank patterns and the plurality of light-emitting elements; and a plurality of signal lines electrically and respectively connecting the plurality of first electrodes to the pixel driving circuit.

In accordance with some embodiments of the first aspect of the present disclosure, the plurality of first electrodes and the plurality of signal lines are constructed to respectively transmit an anode voltage output from the pixel driving circuit to the plurality of light-emitting elements.

In accordance with some embodiments of the first aspect of the present disclosure, the display device further comprises: a plurality of contact electrodes electrically connected to the pixel driving circuit; and at least one second electrode disposed between the first optical layer and the third optical layer and between the second optical layer and the third optical layer, wherein the at least one second electrode is electrically connected to the plurality of contact electrodes.

In accordance with some embodiments of the first aspect of the present disclosure, the second electrode and the plurality of contact electrodes are configured to respectively transmit a cathode voltage output from the pixel driving circuit to the plurality of light-emitting elements.

In accordance with some embodiments of the first aspect of the present disclosure, a material of the first optical layer and a material of the second optical layer are different from each other.

In accordance with some embodiments of the first aspect of the present disclosure, the second optical layer and the third optical layer include different materials.

In accordance with some embodiments of the first aspect of the present disclosure, each of the first optical layer and the third optical layer includes an organic insulating material and light scattering particles dispersed in the organic insulating material.

In accordance with some embodiments of the first aspect of the present disclosure, the first optical layer surrounds a side surface of the bank pattern and a side surface of each of the plurality of light-emitting elements.

In accordance with some embodiments of the first aspect of the present disclosure, an area size of an upper surface of the first optical layer is greater than an area size of a lower surface of the bank pattern.

In accordance with some embodiments of the first aspect of the present disclosure, the second optical layer is disposed on an outer side of the first optical layer, wherein the third optical layer is disposed on top of the first optical layer.

In accordance with some embodiments of the first aspect of the present disclosure, each of the plurality of light-emitting elements is an inorganic light-emitting diode.

In accordance with some embodiments of the first aspect of the present disclosure, the pixel driving circuit is a driver.

A second aspect of the present disclosure provides a display device comprising: a substrate; at least one pixel driving circuit disposed on the substrate; a plurality of bank patterns disposed on the pixel driving circuit; a plurality of light-emitting elements disposed on each of the plurality of bank patterns and electrically connected to the pixel driving circuit; a first optical layer surrounding each of the plurality of light-emitting elements; and a second optical layer disposed on an outer side of the first optical layer, wherein a horizontal width of the first optical layer increases as the first optical layer extends from a lower surface to an upper surface thereof.

In accordance with some embodiments of the second aspect of the present disclosure, the display device further comprises a third optical layer disposed on top of the first optical layer.

In accordance with some embodiments of the second aspect of the present disclosure, a material of the first optical layer and a material of the second optical layer are different from each other.

In accordance with some embodiments of the second aspect of the present disclosure, the first optical layer includes an organic insulating material and light scattering particles dispersed in the organic insulating material, wherein the second optical layer includes an organic insulating material and is free of the light scattering particles.

A third aspect of the present disclosure provides a method for manufacturing a display device, the method comprising: forming a bank pattern on a substrate; disposing a plurality of light-emitting elements on the bank pattern; forming a second optical layer on the substrate such that the second optical layer has one or more open areas defined therein exposing the bank pattern and the plurality of light-emitting elements; forming a first optical layer filling the open area so as to surround the bank pattern and surround a side surface of each of the plurality of light-emitting elements; and disposing a second electrode on the plurality of light-emitting elements, the first optical layer, and the second optical layer.

In accordance with some embodiments of the third aspect of the present disclosure, in the forming of the second optical layer, the one or more open areas include a first open area exposing the bank pattern and a second open area spaced apart from the bank pattern, wherein the second open area is a contact hole area filled with a black matrix.

In accordance with some embodiments of the third aspect of the present disclosure, in the forming of the first optical layer, an area size of an upper surface of the first optical layer is greater than an area size of a lower surface of the bank pattern.

In accordance with some embodiments of the third aspect of the present disclosure, the method further comprises: after disposing the second electrode, disposing a third optical layer on the second electrode; and disposing a black matrix on the first optical layer, the second optical layer, and the third optical layer.

In accordance with some embodiments of the third aspect of the present disclosure, the third optical layer is disposed to overlap the plurality of light-emitting elements and the first optical layer.

In accordance with some embodiments of the third aspect of the present disclosure, the black matrix is disposed to overlap at least one of the light-emitting elements and is disposed to fill the contact hole area.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device comprising:
a substrate;
at least one pixel driving circuit disposed on the substrate;
a plurality of bank patterns disposed on the pixel driving circuit;
a plurality of light-emitting elements disposed on each of the plurality of bank patterns and electrically connected to the pixel driving circuit;
at least one optical layer disposed to surround the plurality of light-emitting elements; and
a black matrix disposed on the optical layer and overlapping at least one of the light-emitting elements,
wherein the at least one optical layer includes a first optical layer, a second optical layer, and a third optical layer.

2. The display device of claim 1, wherein the display device further comprises:
a plurality of first electrodes respectively disposed between each of the plurality of bank patterns and the plurality of light-emitting elements; and
a plurality of signal lines electrically and respectively connecting the plurality of first electrodes to the pixel driving circuit.

3. The display device of claim 2, wherein the plurality of first electrodes and the plurality of signal lines are constructed to respectively transmit an anode voltage output from the pixel driving circuit to the plurality of light-emitting elements.

4. The display device of claim 1, wherein the display device further comprises:
a plurality of contact electrodes electrically connected to the pixel driving circuit; and
at least one second electrode disposed between the first optical layer and the third optical layer and between the second optical layer and the third optical layer, wherein the at least one second electrode is electrically connected to the plurality of contact electrodes.

5. The display device of claim 4, wherein the second electrode and the plurality of contact electrodes are configured to respectively transmit a cathode voltage output from the pixel driving circuit to the plurality of light-emitting elements.

6. The display device of claim 1, wherein a material of the first optical layer and a material of the second optical layer are different from each other.

7. The display device of claim 1, wherein the second optical layer and the third optical layer include different materials.

8. The display device of claim 1, wherein each of the first optical layer and the third optical layer includes an organic insulating material and light scattering particles dispersed in the organic insulating material.

9. The display device of claim 1, wherein the first optical layer surrounds a side surface of the bank pattern and a side surface of each of the plurality of light-emitting elements.

10. The display device of claim 9, wherein an area size of an upper surface of the first optical layer is greater than an area size of a lower surface of the bank pattern.

11. The display device of claim 1, wherein the second optical layer is disposed on an outer side of the first optical layer,
wherein the third optical layer is disposed on top of the first optical layer.

12. The display device of claim 1, wherein each of the plurality of light-emitting elements is an inorganic light-emitting diode.

13. The display device of claim 1, wherein the pixel driving circuit is a driver.

14. A display device comprising:
a substrate;
at least one pixel driving circuit disposed on the substrate;
a plurality of bank patterns disposed on the pixel driving circuit;
a plurality of light-emitting elements disposed on each of the plurality of bank patterns and electrically connected to the pixel driving circuit;
a first optical layer surrounding each of the plurality of light-emitting elements; and
a second optical layer disposed on an outer side of the first optical layer,
wherein a horizontal width of the first optical layer increases as the first optical layer extends from a lower surface to an upper surface thereof.

15. The display device of claim 14, wherein the display device further comprises a third optical layer disposed on top of the first optical layer.

16. The display device of claim 14, wherein a material of the first optical layer and a material of the second optical layer are different from each other.

17. The display device of claim 14, wherein the first optical layer includes an organic insulating material and light scattering particles dispersed in the organic insulating material,
wherein the second optical layer includes an organic insulating material and is free of the light scattering particles.

18. A method for manufacturing a display device, the method comprising:
forming a bank pattern on a substrate;
disposing a plurality of light-emitting elements on the bank pattern;
forming a second optical layer on the substrate such that the second optical layer has one or more open areas defined therein exposing the bank pattern and the plurality of light-emitting elements;
forming a first optical layer filling the open area so as to surround the bank pattern and surround a side surface of each of the plurality of light-emitting elements; and
disposing a second electrode on the plurality of light-emitting elements, the first optical layer, and the second optical layer.

19. The method of claim 18, wherein in the forming of the second optical layer, the one or more open areas include a first open area exposing the bank pattern and a second open area spaced apart from the bank pattern,
wherein the second open area is a contact hole area filled with a black matrix.

20. The method of claim 18, wherein in the forming of the first optical layer, an area size of an upper surface of the first optical layer is greater than an area size of a lower surface of the bank pattern.

21. The method of claim 18, wherein the method further comprises:
after disposing the second electrode, disposing a third optical layer on the second electrode; and
disposing a black matrix on the first optical layer, the second optical layer, and the third optical layer.

22. The method of claim 21, wherein the third optical layer is disposed to overlap the plurality of light-emitting elements and the first optical layer.

23. The method of claim 19, wherein the black matrix is disposed to overlap at least one of the light-emitting elements and is disposed to fill the contact hole area.
